(19) United States
(12) Patent Application Publication
(10) Pub. No.: US 2016/0247675 A1
(43) Pub. Date: Aug. 25, 2016

(54) METHOD FOR MANUFACTURING THIN FILM

(71) Applicant: WONIK IPS CO., LTD., Gyeonggi-do (KR)

(72) Inventors: So-Yeon PARK, Bucheon-Si, Gyeonggi-Do (KR); Young-Soo KWON, Yongin-Si, Gyeonggi-Do (KR)

(21) Appl. No.: 15/025,548

(22) PCT Filed: Jun. 18, 2013
(86) PCT No.: PCT/KR2013/005373

§ 371 Date: Mar. 28, 2016

(51) Int. Cl. H01L 21/02

(52) U.S. Cl. CPC H01L 21/02274; H01L 21/0262; H01L 21/02126; H01L 21/02164; H01L 21/0217

(57) ABSTRACT

The present invention relates to a method for manufacturing a thin film, comprising the steps of: preparing a substrate; preparing a raw material comprising a compound consisting of SiH2, as a basic structure thereof, and a functional group, including at least one of carbon, oxygen, and nitrogen, linearly bonded to both sides of the basic structure; vaporizing the raw material, and loading the substrate into a chamber; and providing the vaporized raw material to the inside of the chamber. Furthermore, the present invention is capable of depositing a high-quality thin film under various processing conditions; manufacturing a thin film within a wide range of processing temperatures, processing pressures, etc.; and utilizing various methods and equipment for manufacturing a thin film.

### TECHNICAL FIELD

The present invention relates to a method for manufacturing a thin film, and more particularly to a method for manufacturing a thin film which allows large process margin and easy process control.

### BACKGROUND ART

Various thin films are required for manufacturing electronic devices such as a semiconductor memory on a substrate. That is, when a semiconductor device is manufactured, various thin films are formed on a substrate and the thin films thus formed are patterned by photolithography to form a device structure.

Thin films are divided into electrically conductive films, dielectric films, insulation films and so forth depending on materials therefor and a method for manufacturing such thin films may be varied. There are roughly physical and chemical methods to form thin films. Recently, to form a semiconductor device, chemical vapor deposition (CVD) is usually used where a thin film of a metal, dielectric material or insulator are formed on a substrate by chemical reactions of gases. Also, an atomic layer deposition (ALD) method is used when a micro thin film is required as a device is miniaturized.

Generally, an insulator thin film, in particular a silicon dioxide (SiO₂) thin film which is most widely used in manufacturing a semiconductor device is formed using TEOS (tetraethyl orthosilicate) as a raw material. That is, gaseous TEOS and oxygen are flowed into a process chamber with a substrate loaded and the substrate is heated above a desired temperature to cause reactions on a surface of the substrate, thereby forming a silicon oxide film.

To easily form a silicon oxide film with high quality using TEOS, plasma enhanced CVD (PECVD) is used. That is, oxygen and gaseous TEOS is flowed into a process chamber and plasma is generated within the chamber. Then, the introduced gases are activated by plasma in order to grow a silicon oxide film on a substrate. For example, the patent document below discloses the technique of forming a silicon oxide (SiO₂) film from TEOS using the PECVD method.

However, even if a silicon oxide film is manufactured using TEOS and plasma, a temperature range for forming a thin film is limited. That is, a deposition process is not fully performed at a temperature below 100 degrees, a thin film formed at 300 degrees or less has not good quality enough to apply to practical use, and re-reaction of decomposed raw material, i.e., TEOS is caused at a temperature above 500 degrees so it may adversely affect the resulting thin film after process is completed or particles may be generated.

Prior art document: U.S. Pat. No. 5,362,526

### DISCLOSURE OF THE INVENTION

### Technical Problem

The present invention provides a method of manufacturing a thin film which allows large process margin. That is, the present invention provides a method of manufacturing a thin film which allows use of various conditions and apparatuses.

The present invention provides a method of manufacturing a thin film which is capable of manufacturing thin films having different properties using a single raw material.

The present invention provides a method of manufacturing a thin film which is capable of easily controlling processes and obtaining a thin film having good breakdown voltage.

### Technical Solution

According to an embodiment, the present invention provides a method of manufacturing a thin film which includes the steps of: providing a substrate; providing a raw material; vaporizing the raw material and loading the substrate into a chamber; and supplying the vaporized raw material to an interior of the chamber wherein the raw material are a precursor including at least one of the following chemical formulae.

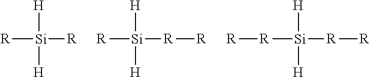

(wherein R is a functional group)

Further, a method of manufacturing a thin film may also include the steps of: providing a substrate; providing a raw material including a compound which has a basic structure of SiH₂ and functional groups including at least one of carbon, oxygen and nitrogen linearly coupled to both sides of the basic structure; vaporizing the raw material and loading the substrate into a chamber; and supplying the vaporized raw material to an interior of the chamber.

A reaction gas may be supplied during or before the vaporized raw material is supplied and reacted with the raw material to form a thin film. The reaction gas may include at least one selected from an oxygen-containing gas, a nitrogen-containing gas, a hydrocarbon compound (CxHy, where 1≦x≦9, 4≦y≦20 and y>2x), a boron-containing gas and a silicon-containing gas.

The functional groups of the raw material may include at least one selected from a methyl group (—CH₃), an ethyl group (—C₂H₅), a benzyl group (—CH₂—C₆H₅), a phenyl group (—C₆H₅), an amine group (—NH₂), a nitro group (—NO), a hydroxyl group (—OH), a formyl group (—CHO) and a carboxyl group (—COOH).

A thin film formed on a substrate by the method described herein may serve as an insulation film containing silicon, and the insulation film may include at least one of an oxide film, a nitride film, a carbide film, an oxide-nitride film, a carbide-nitride film, a boride-nitride film, and a carbide-boride-nitride film.

A thin film may be formed on a substrate through chemical vapor deposition or atomic layer deposition. A single substrate or a plurality of substrates may be loaded into a chamber of an apparatus for deposition in manufacturing a thin film.

A temperature for manufacturing a thin film may be preferably in a range of 80 to 700 degrees and a pressure for manufacturing a thin film is preferably in a range of 1 to 700 torr.

A thin film may be deposited using plasma. In particular, a silicon oxide film may be formed in such a way that plasma is generated within a chamber of a thin film-manufacturing apparatus and a thin film-manufacturing temperature is controlled in a range of 80 to 250 degrees.

### Advantageous Effects

Since a method of manufacturing a thin film according to an embodiment of the present invention forms a thin film using a new raw material, a high quality thin film can be deposited under various process conditions. That is, a thin film can be formed using a broad range of process temperature and pressure as well as various manufacture methods and apparatuses. For example, a thin film can be manufactured by deposition methods such as CVD, PECVD, SACVD (subatmospheric CVD), RACVD (radical assisted CVD), RPCVD (remote plasma CVD), ALD, and the like. The present invention can also be applied to an apparatus for loading a substrate into a vacuum chamber and a furnace-type apparatus for loading a substrate into a tube.

Further, by using the method described herein, thin films having different properties can be manufactured using a single raw material. That is, by adjusting functional groups of raw materials and reaction gases, thin films such as nitride film, carbide film, oxide-nitride film, carbide-nitride film, boride-nitride film, carbide-boride-nitride film as well as silicon oxide film can be manufactured.

Furthermore, since a thermally stable raw material is used in the method described herein, a low temperature deposition and easy process control is allowed, so that a thin film having good electric and mechanical properties can be obtained. For example, the resulting insulation thin film has improved breakdown voltage property and enhanced densification and density.

Moreover, process margin is increased in the method described herein, so that productivity can be drastically improved.

### BRIEF DESCRIPTION OF THE DRAWINGS

FIG. 1 is a simple flow chart showing a method of manufacturing a thin film according to the present invention.

FIG. 2A to FIG. 2D are a schematic view showing chemical structures of raw materials according to the present invention.

FIG. 3 is a cross-sectional view of an apparatus for manufacturing a thin film according to an example of the present invention.

FIG. 4 is a flow chart showing the sequence of a method for manufacturing a thin film according to an example of the present invention.

FIG. 5 is a graph of the results from FTIR analysis of silicon oxide films formed using various conditions.

FIG. 6 is graphs of the results from FTIR analysis of silicon nitride films formed using various conditions.

### MODE FOR CARRYING OUT THE INVENTION

Hereinafter, embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

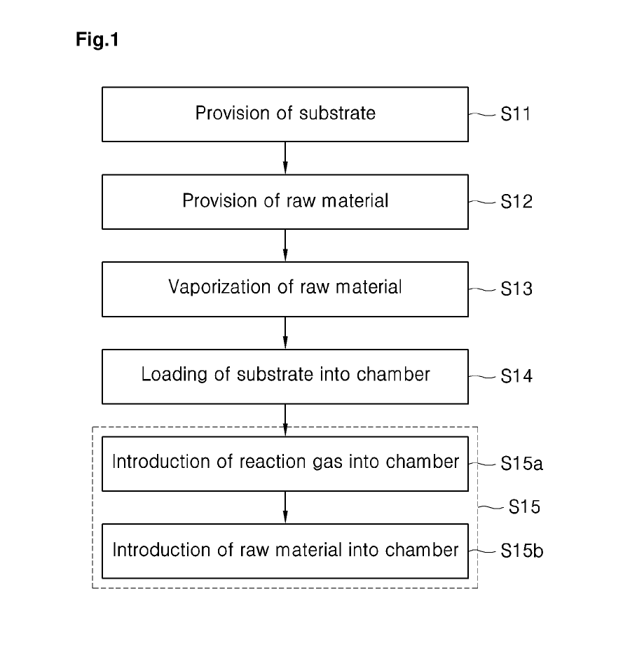

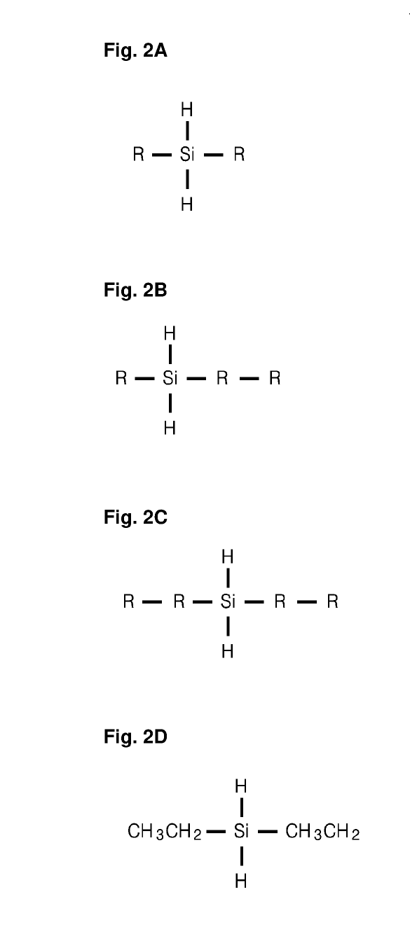

Now, preferred embodiments according to the present invention will be described with reference to the accompanying drawings. FIG. 1 is a flow chart showing a method of manufacturing a thin film according to the present invention and FIG. 2A to FIG. 2D are a view showing chemical structures of raw materials according to the present invention. All of temperatures indicated below are Celsius degree.

Referring to FIG. 1, a method of manufacturing a thin film includes the steps of providing a substrate; providing a raw material; vaporizing the raw material and loading the substrate into a chamber; and supplying the vaporized raw material to the chamber.

Firstly, a substrate S is provided (S11). As the substrate S, for example, a silicon wafer may be used, and if necessary, a substrate made from various materials may be used.

Then, a raw material is provided (S12). The raw material includes an organic silane precursor that is a liquid state at room temperature. Specifically, the raw material includes a compound which has a basic structure of SiH₂ and functional groups including at least one of carbon, oxygen and nitrogen linearly coupled to both sides of the basic structure. Such raw materials may be represented by chemical formulas such as FIG. 2A to FIG. 2C. The functional groups may include at least one selected from methyl group (—CH₃), ethyl group (—C₂H₅), benzyl group (—CH₂—C₆H₅), phenyl group (—C₆H₅), amine group (—NH₂), nitro group (—NO), hydroxyl group (—OH), formyl group (—CHO) and carboxyl group (—COOH). The same functional group may be bound to each of both sides, e.g., right and left sides of the basic structure ((a) in FIG. 2A), one functional group may be bound to one side of the basic structure and two functional groups may be bound to another side (FIG. 2B), or two functional groups may be bound to each of both sides of the basic structure where the functional groups may be the same or different in both sides (FIG. 2C). Si—H bonding energy in the basic SiH₂ structure is 75 kJ/mol. Depending on functional groups bound to the basic structure, a bond such as Si—O (110 kJ/mol), Si—C (76 kJ/mol), O—C (85.5 kJ/mol), C—H (99 kJ/mol) and N—H (93 kJ/mol) may be formed. Since the bonding energy between silicon and bound functional groups is greater than the bonding energy of Si—H, energy required to decompose a raw material (source) is increased as the number of functional group is increased.

Since the dissociation energy of decomposition is different depending on a functional group, powers having different levels may be applied to generate plasma that is used in manufacturing a thin film. Thus, by adjusting functional groups, raw materials having different dissociation energies and decomposition conditions may be produced. This idea may be adopted for forming a desired thin film. Also, a thin film having desired properties may be manufactured by varying a reaction gas depending on bonds present in a raw material. For example, where two OC₂H₅ groups are bound to SiH₂, a thin film of SiO₂ or SiON may be formed by adjusting a level of power applied or varying a reaction gas (N₂O, O₂, etc.).

Then, a raw material selected to form a desired thin film is vaporized (S13). That is, the raw material present as liquid at room temperature is converted to a gaseous state before it is introduced into a chamber. The raw material is converted to gas using a vaporization apparatus such as vaporizer or bubbler known in the art. When a bubbler is used, a liquid raw material may be bubbled using gas such as argon (Ar), hydrogen (H2), oxygen (O2), nitrogen (N2), helium (He) and the like.

After or during the raw material is vaporized, a substrate is loaded into a chamber (S14). That is, the substrate S, e.g., a silicon wafer is mounted on a substrate-supporting part in the chamber. A single substrate or a plurality of substrates S may be mounted on the substrate-supporting part. The substrate may be heated to an appropriate temperature using a chuck heater provided within the substrate-supporting part. After the substrate S is mounted on the substrate-supporting part, vacuum pressure is adjusted to a desired level, and a temperature of the substrate S is controlled by heating the substrate-supporting part.

Then, the substrate is exposed to various gases to form a thin film (S15). That is, a vaporized raw material and a reaction gas are introduced into a chamber. The vaporized raw material includes elements constituting main components of a thin film, and the reaction gas is reacted with the raw material to form the thin film. For example, when a silicon oxide thin film is formed, a material including silicon (e.g., C₄H₁₂Si) is used as the raw material and oxygen-containing gas such as oxygen or ozone is used as the reaction gas. The raw material and the reaction gas may be concurrently introduced, or either one may be firstly introduced. For example, the reaction gas is introduced into the chamber (S15a), and then the vaporized raw material is introduced (S15b). Of course, a thin film may be also manufactured using only vaporized raw material without any reaction gas depending on functional groups of selected raw material and properties of the resulting thin film.

The vaporized raw material may preferably be supplied together with a carrier gas. The carrier gas allows smooth flow and accurate control of the gaseous raw material. The carrier gas is preferably an inert gas which does not affect the raw material. For example, the carrier gas includes at least one selected from helium, nitrogen and argon. The reaction gas is selected depending on properties of the resulting thin film, and in this embodiment, includes at least one selected from oxygen-containing gas, nitrogen-containing gas, hydrocarbon compound (CxHy, 1≦x≦9, 4≦y≦20, y>2x), boron-containing gas and silicon-containing gas. In addition to the reaction gas, an auxiliary gas may be additionally used to promote the formation of a thin film. Of course, the use and type of auxiliary gas may be determined depending on a thin film to be formed and a reaction gas.

After the raw material alone or the raw material with the reaction gas is supplied to a substrate, a reaction for forming a thin film is started and a thin film is grown on the substrate that is controlled to an appropriate temperature. A process temperature during forming a thin film, i.e., a temperature of the substrate is preferably controlled in the range of 80 to 700 degrees, and a pressure during forming a thin film, i.e., a process pressure is preferably in the range of 1 to 700 torr. If the substrate temperature is less than 80 degrees, particles are produced while a thin film is formed so quality of the film is lowered. If the temperature is greater than 700 degrees, durability of the chuck heater in the substrate-supporting part is deteriorated and accurate temperature control is difficult. If the process pressure is less than 1 torr, a deposition rate is too low to form a thin film and accurate pressure control of total amount of process gases is difficult. If the pressure is greater than 700 torr, a deposition rate is too high to obtain a dense thin film and process control such as particle control is difficult since the pressure is comparable to atmospheric pressure. The process temperature and pressure may be varied depending on a thin film-manufacturing method and an apparatus.

After a thin film is formed in a desired thickness, the substrate is unloaded outside the chamber and the deposition process is terminated.

Although a general CVD process has been described, a thin film may be manufactured using various methods or apparatuses. That is, a thin film may be manufactured by deposition methods such as SACVD (sub-atmospheric CVD), RACVD (radical assisted CVD), RPCVD (remote plasma CVD), PECVD, ALD, or the like. In SACVD, deposition is carried out while maintaining the process pressure in the range of 200 to 700 torr that is slight lower than atmospheric pressure and gases are injected similarly to CVD. That is, a raw material and reaction gases are introduced into the chamber via a gas injection port, and then a thin film is deposited under high pressure. All PECVD, RPCVD and RACVD utilize plasma. PECVD generally generates plasma within a chamber, RPCVD generates plasma outside a chamber, i.e., a remote location apart from the chamber and supplies active species to an interior of the chamber, and RACVD generates plasma within a showerhead coupled to a chamber and provides active species on a substrate. Such methods which use plasma in the manufacture of a thin film have advantages that a reaction gas may easily be activated and deposited at a low temperature, as well as that a high quality thin film may be formed using low energy at a high temperature. In RACVD or RPCVD, after gas is activated by remote plasma and introduced into a chamber, a deposition process is carried out. Thus, they also have an advantage that damage to a substrate may be minimized. In case of such methods utilizing plasma, a low temperature process and a broad temperature range of 80 to 700 degrees is possible. Also, the process may be preferably performed in low pressure in the range of 1 to 10 torr. In an atomic layer deposition (ALD) method, process gases are separately provided and a thin film is formed by surface saturation of the process gases. That is, a source gas is supplied inside a chamber and reacted with a surface of a substrate to chemically deposit a single atomic layer on the surface of the substrate. Then, a purge gas is supplied to remove the remaining or physically absorbed source gas by the purge gas. Then, a reaction gas is supplied on a top of the first single atomic layer and the reaction gas is reacted with the source gas to grow a second layer. Then, the purge gas is supplied to remove the reaction gas that is not reacted with the first layer. These processes are repeated to form a thin film. Herein, since the aforementioned raw materials are used as the source gas, a thin film may be manufactured by an ALD method. Of course, the ALD method may also use plasma as described above. Further, a thin film may be also manufactured using a furnace-type apparatus loading a substrate into a tube as well as an apparatus loading a substrate into a vacuum chamber.

By using the method of manufacturing a thin film as described above, thin films having different properties may be manufactured depending on a raw material and a reaction gas. For example, a silicon oxide film, a nitride film, a carbide film, an oxide-nitride film, a carbide-nitride film, a boride-nitride film, a carbide-boride-nitride film, and the like may be manufactured. Firstly, in case of a raw material having a functional group such as methyl group (—CH₃), ethyl group (—C₂H₅), benzyl group (—CH₂—C₆H₅), phenyl group (—C₆H₅) bound to the basic structure of SiH₂ (raw material 1), various insulator thin film may be formed by using a single reaction gas or a plurality of reaction gases (see Table 1 below in which thin films made using the raw material 1 are exemplified).

TABLE 1

| | | The resulting |
|---|---|---|
| Reaction gas | Auxiliary gas | thin film |
| O₂ | N₂O, NO | SiO₂ |
| — | — | SiC |
| N₂, NH₃ | — | SiN |
| N₂O, NO | — | SiON |
| N₂, NH₃ | — | SiCN |
| (N₂, NH₃) + CxHy | — | SiCN |
| BxHy + (N₂, NH₃) | — | SiBN |
| BxHy + CxHy | — | SiCBN |

In said table, the plus (+) symbol is indicated that gases are together used, and the other gas may be alone or together used. In CxHy, x and y satisfy the condition of 1≦x≦9, 4≦y≦20, y>2x; BxHy may be selected among BH₃, B₂H₄, B₂H₆, B₃H₈, B₄H₁₀, B₅H₉, B₅H₁₁, B₆H₁₀, B₆H₁₂, B₈H₁₂, B₉H₁₅ and B₁₀H₁₄. It applies similarly to tables below.

Also, in case of a raw material having a functional group such as amine group (—NH₂) and nitro group (—NO) bound to the basic structure of SiH₂ (raw material 2), various insulator thin film may be formed by using a single reaction gas or a plurality of reaction gases (see Table 2 below in which thin films made using the raw material 2 are exemplified).

TABLE 2

| | | The resulting |
|---|---|---|
| Reaction gas | Auxiliary gas | thin film |
| O₂ | N₂O, NO | SiO₂ |
| — | — | SiN |
| N₂, NH₃ | — | SiN |
| N₂ | — | SiON |
| N₂O, NO | — | SiON |
| CxHy | — | SiCN |
| (N₂, NH₃) + CxHy | — | SiCN |
| BxHy | — | SiBN |
| BxHy + (N₂, NH₃) | — | SiBN |
| BxHy + CxHy | — | SiCBN |

Also, in case of a raw material having a functional group such as hydroxyl group (—OH), formyl group (—CHO), carboxyl group (—COOH) bound to the basic structure of SiH₂ (raw material 3), various insulator thin film may be formed by using a single reaction gas or a plurality of reaction gases (see Table 3 below in which thin films made using the raw material 3 are exemplified).

TABLE 3

| | | The resulting |
|---|---|---|
| Reaction gas | Auxiliary gas | thin film |
| — | — | SiO₂ |
| O₂ | N₂O, NO | SiO₂ |
| N₂, NH₃ | — | SiN |
| N₂ | — | SiON |
| N₂O, NO | — | SiON |
| CxHy | — | SiCN |
| N₂, NH₃ | — | SiCN |
| (N₂, NH₃) + CxHy | — | SiCN |
| BxHy + (N₂, NH₃) | — | SiBN |
| BxHy + CxHy | — | SiCBN |

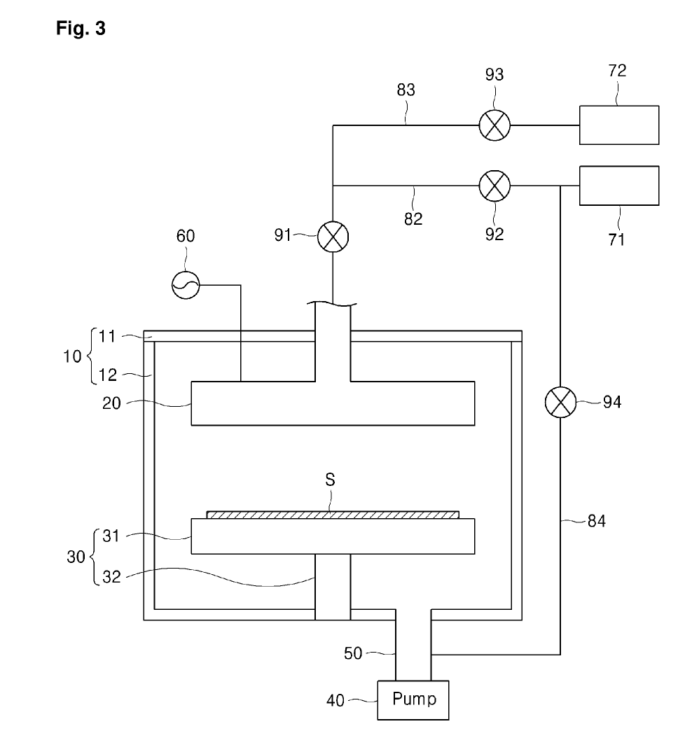

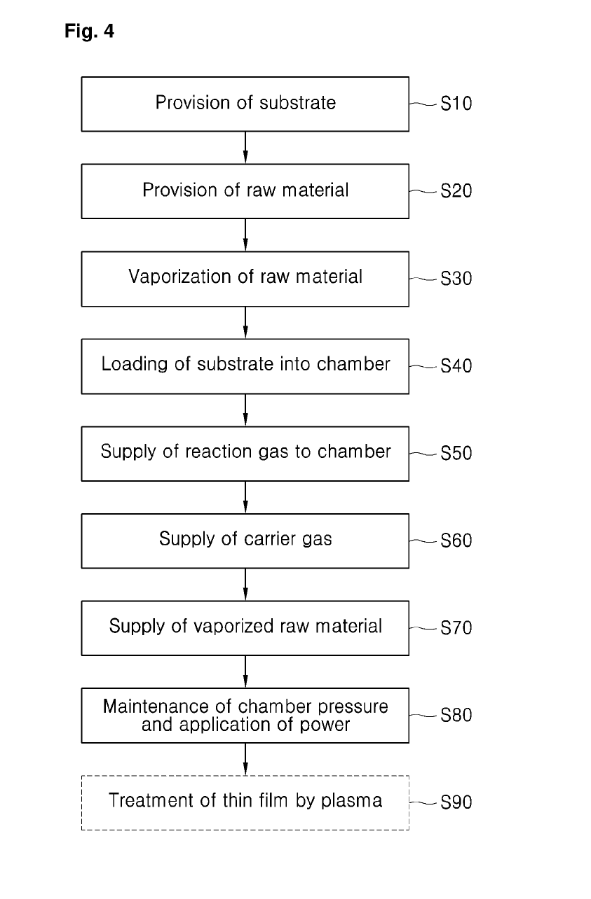

The following description specifically shows an example of an apparatus and a method for manufacturing an oxide film by PECVD method. FIG. 3 is a cross-sectional view of an apparatus for manufacturing a thin film according to an example of the present invention, and FIG. 4 is a flow chart showing the sequence of a method for manufacturing a thin film according to an example of the present invention.

Firstly, an apparatus for manufacturing a thin film includes a chamber 10, a substrate-supporting part 30 and a gas injection unit 20. The apparatus also includes a gas-supplying unit for supplying various gases to the gas injection unit 20 and a unit for applying power to the gas injection unit.

The chamber 10 includes a main body 12 with a top portion opened and a top lid 11 configured to open and close and installed in the top portion. When the top lid 11 is coupled to the top portion of the main body 12 to close an interior of the main body 12, a space where a substrate S treatment process such as deposition is performed is formed inside the chamber. Since the space should be typically a vacuum state, an exhaust port is formed in a desired position of the chamber 10 to discharge gas present in the space, and the exhaust port is connected to an exhaust pipe which is connected to an external vacuum pump 40 provided outside. Also, a through-hole through which a rotation shaft is inserted is provided in a bottom surface of the main body 12, as will be described below. A gate valve (not shown) is formed in a sidewall of the main body 12 to insert or remove the chamber 10.

The substrate-supporting part 30 is configured to support a substrate and includes a supporting plate 31 and a rotation shaft 32. The supporting plate 31 is a plate of circular shape and horizontally provided inside the chamber 10. The rotation shaft 32 is vertically connected to a bottom surface of the supporting plate 31. The rotation shaft 32 is connected to an external driving unit (not shown) such as motor through the through-hole to elevate and rotate the supporting plate 31. Also, a heater (not shown) is provided in a lower side or interior of the supporting plate 31 to heat the substrate S to a constant process temperature.

Also, the gas injection unit 20 is provided apart from a top portion of the substrate-supporting part 30 and injects process gases such as vaporized raw material, carrier gas, reaction gas, auxiliary gas and so forth toward the substrate-supporting part 30. The gas injection unit 20 is a showerhead-type injection unit and injects different gases introduced from outside and mixed therein toward the substrate S. Of course, in addition to the showerhead-type injection unit, various injection devices such as injector or nozzle may be used.

Also, the gas injection unit 20 is connected to gas-supplying units and gas-supplying lines for supplying various process gases. Firstly, it includes a raw material-supplying unit 71, a raw material-supplying line 82 connected between the raw material-supplying unit 71 and the gas injection unit 20 and a first valve 92 provided on the raw material-supplying line 82 and configured to control supply of a raw material. The raw material-supplying unit 71 includes a reservoir configured to store a liquid raw material, a vaporization device configured to receive and vaporize the liquid raw material and a carrier gas-supplying device configured to store and supply a carrier gas. The vaporization device may be a vaporizer or a bubbler, which will not be described in detail as a general device. A discharge line for discharging the vaporized raw material is connected to a discharge line of the carrier gas-supplying device. These discharge lines are connected to the raw material-supplying line 82. Also, a raw material-discharging line 84 is connected between the raw material-supplying unit 71 and an exhaust pipe 50 of the chamber 10, and a third valve 94 is provided on the raw material-discharging line 84 to control discharge of the raw material. A reaction gas-supplying unit 72 and a reaction gas-supplying line 83 for supplying a reaction gas is connected to the gas injection unit 20, and a second valve 93 is provided on the reaction gas-supplying line 83 to control supply of the reaction gas. The raw material-supplying line 82 and the reaction gas-supplying line 83 are coupled to each other outside the chamber before they are connected to the gas injection unit 20, and a main control valve 91 may be provided on the lines coupled. Of course, the raw material-supplying line 82 and the reaction gas-supplying line 83 may be separately connected to the gas injection unit 20 to supply individual gas.

The apparatus for manufacturing a thin film includes a plasma-generating unit. That is, the plasma-generating unit may be provided to generate plasma inside the chamber and exits various process gases to active species. For example, a power-supplying unit 60 is connected to the gas injection unit 20, and hence, a capacitively coupled plasma (CCP) method may be utilized wherein RF (radio frequency) power is applied to the gas injection unit 20 on a top portion of a substrate in the chamber 10 and the substrate-supporting unit is grounded to exit plasma by RF in a reaction space for deposition inside the chamber. In this case, RF power is applied as power, and at least one of high frequency RF power and low frequency RF power having a frequency lower than the high frequency RF power may be used. That is, high frequency RF power and low frequency RF power may be applied to a showerhead alone or in combination. A frequency band of the high frequency RF power is about 3˜30 MHz, and a frequency band of the low frequency RF power is about 30˜3000 KHz. For example, high frequency RF power of 13.56 MHz and low frequency RF power of 400 KHz may be used. Also, the high frequency RF power may be used in the range of about 100 to 700 W and the low frequency RF power may be used in the range of 0 to 600 W. Total power of high frequency RF power and low frequency RF power is preferably controlled to 100 to 1300 W. Preferably, the high frequency RF power may be changed to 100 to 1000 W, or the low frequency RF power may be changed to 100 to 900 W. Herein, a level of RF power is within a range required to decompose or activate a raw material and a reaction gas. In addition, when the plasma-generating unit includes a coil, plasma may be generated by inductive coupling.

When a deposition process is performed by using the apparatus described herein, various process gases are supplied to a top portion of the substrate S through the gas injection unit 20 and plasma is generated inside the chamber 10. Active species are supplied on the substrate and a thin film is formed. The remaining gases and byproducts are discharged outside through the exhaust pipe 50. Of course, the apparatus may be modified in many configurations other than the configuration as described above.

The following description specifically shows an example of a method for manufacturing an oxide thin film. In this example, a process for manufacturing a silicon oxide film by PECVD is exemplified wherein a raw material having CxHy as a functional group is used. The contents previously described will be omitted from the following description.

A method for manufacturing a thin film includes the steps of providing a substrate, providing a raw material, vaporizing the raw material, loading the substrate into a chamber and supplying the vaporized raw material to an interior of the chamber. Since the steps until the substrate is loaded (S10˜540) are the same as previously described, they will not be described in detail.

In this example, an organic silane having CxHy (1≦x≦9, 4≦y≦20, y>2x) as a functional group is used as the raw material. That is, a compound is used wherein a basic structure is SiH₂ and functional groups including carbon and hydrogen are linearly coupled to both sides of the basic structure. For example, a compound having a structure wherein CH₃—CH₂ is linearly bound to the central Si is used (see FIG. 2D). This C₄H₁₂Si material has low vaporization temperature, small molecular weight and high vapor pressure as compared to a conventional TEOS. That is, TEOS has the vaporization temperature of 168 degrees, the molecular weight of 208 and the vapor pressure of 1.2 torr at 20 degrees. In contrast, the C₄H₁₂Si material has the vaporization temperature of 56 degrees, the molecular weight of 88.2 and the vapor pressure of about 208 torr at 20 degrees. Thus, the C₄H₁₂Si material may be vaporized and easily deposited as a thin film at a low temperature. Also, the TEOS source is reacted with a reaction gas after O—C bond (85.5 KJ/mol) is broken due to its structure, while C₄H₁₂Si is reacted with a reaction gas after Si—H bond (75 KJ/mol) is broken. Thus, since C₄H₁₂Si has initial dissociation energy lower than that of TEOS, C₄H₁₂Si is beneficial to deposition at a low temperature.

After the substrate is loaded into the chamber, various gases are supplied (S60 to S70). A process temperature is controlled in the range of 80 to 250 degrees. If the process temperature is less than 80 degrees, particles are produced while a thin film is formed so quality of the film is lowered. If the temperature is greater than 250 degrees, it may adversely affect subsequent processes. The process temperature may be more increased if it does not affect subsequent processes. The process temperature may also be more increased depending on components of a thin film to be formed. Firstly, a reaction gas, oxygen is supplied through the reaction gas-supplying unit 72 and the reaction gas-supplying line 83. Once oxygen is introduced into the chamber through the gas injection unit 20, a carrier gas (e.g., helium) and the vaporized C₄H₁₂Si raw material is flowed into the exhaust pipe 50 through the raw material-discharging line 84 and the third valve 94. Thereby, gas flow may be stabilized before the C₄H₁₂Si material is introduce into the chamber. That is, it is to introduce gases into the chamber 10 after flow fluctuation due to initial flow of C₄H₁₂Si material and carrier gas is discharged through the exhaust pipe and gas flow is stabilized. After the flow of C₄H₁₂Si raw material and carrier gas is stabilized, the third valve 94 is switched to OFF and the first valve 92 is switched to ON, and the C₄H₁₂Si material and the carrier gas are injected on the substrate through the gas injection unit 20. That is, the reaction gas, the vaporized raw material and the carrier gas are mixed in the showerhead and injected toward the substrate.

Once these process gases are introduced into the chamber 10 and a desired pressure is maintained, RF power is applied to the gas injection unit 20, i.e., the showerhead (S80). A process pressure is preferably maintained in the range of 1 to 10 torr. If the process pressure is less than 1 torr, a deposition rate on the substrate is too low to form a thin film and productivity is decreased. If the pressure is greater than 10 torr, a deposition rate is too high to obtain a dense film. Once the process gases are introduced and plasma is generated, the gases are converted to active species. These active species are moved on the substrate and oxygen is reacted with silicon present in C₄H₁₂Si to form a thin film. The power and pressure is maintained for a desired period until a thin film having a desired thickness is formed.

After the formation of a thin film is terminated, the resulting thin film may be treated by plasma (S90). That is, after a thin film is manufactured, a surface of the thin film is treated by plasma for a desired period by generating oxygen or N₂O plasma to remove unreacted bonds or particles residue in the surface. After all processes are completed, the substrate is unloaded outside the chamber and the substrate is transferred to a subsequent process.

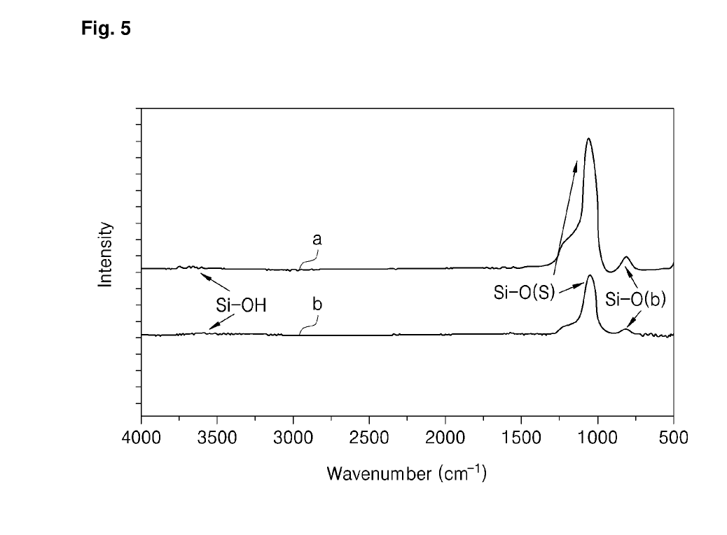

The quality of the silicon oxide film thus formed was evaluated. FIG. 5 is a graph of the results from FTIR (Fourier transform infrared spectroscopy) analysis of silicon oxide films formed using various conditions. In FIG. 5, (a) represents a conventional silicon oxide film manufactured using TEOS at the process temperature of 350 degrees, and (b) represents a silicon oxide film manufactured using C₄H₁₂Si at the process temperature of 150 degrees. As can be seen from FIG. 5, the oxide film formed at a low temperature according to this example showed spectrum illustrating stable bonds with a bonding structure similar to an oxide film formed at a high temperature even though it was formed at relatively low temperature as compared to the TEOS process. Also, voltage was applied to the oxide film formed in this example to measure a breakdown voltage. The result showed stable voltage property without current leakage and the breakdown was started when it was greater than 9 MV/cm. Thus, although a silicon oxide film is formed at a low temperature in this example, since the dissociation energy of raw material is low, the raw material is well reacted with a reaction gas in a chamber, thereby forming a dense thin film.

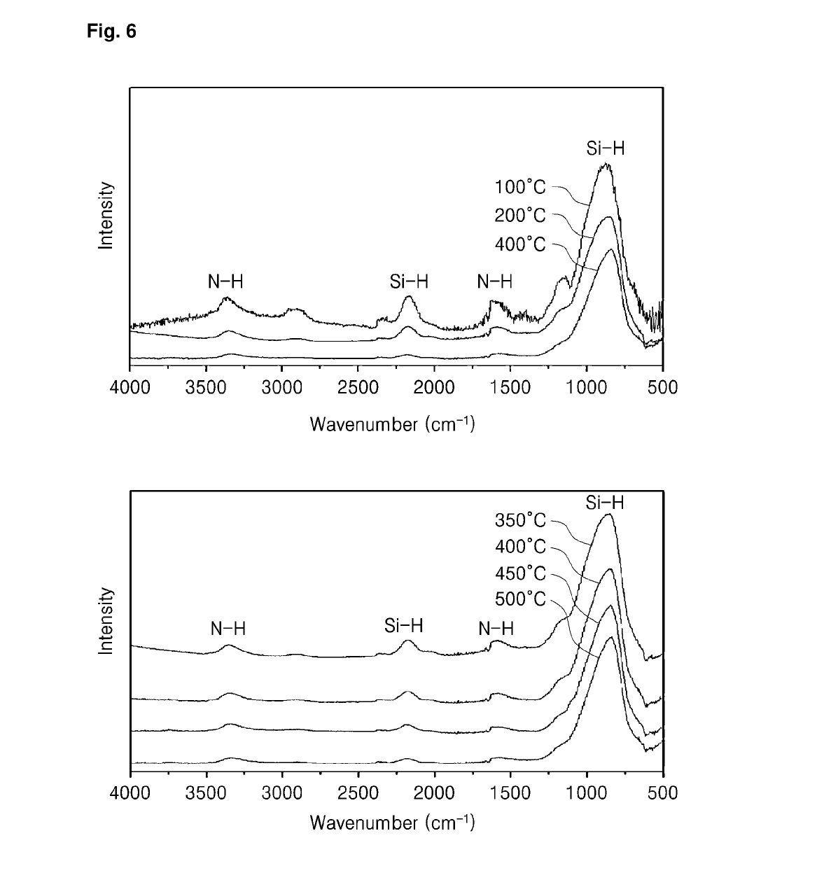

Although the silicon oxide film manufactured using C₄H₁₂Si as a raw material and oxygen as a reaction gas was exemplified in this example, various thin films may be manufactured by varying the reaction gas. For example, a silicon nitride film may be formed by the same procedure as described above using a nitrogen-containing gas such as nitrogen (N2), ammonia (NH₃) and so forth. That is, the silicon nitride film may be formed by a reaction between silicon present in C₄H₁₂Si and nitrogen present in the reaction gas. A silicon nitride oxide formed using nitrogen (N₂) and ammonia (NH₃) as a reaction gas at each process temperature (100 to 500 degrees) was evaluated. FIG. 6 is a graph of the results from FTIR analysis of silicon nitride films formed using various conditions. As can be seen from FIG. 6, silicon nitride films with stable bonds between elements were formed in the board range of process temperature.

Although the present invention has been described with reference to the specific embodiments, it is not limited thereto. Therefore, it will be readily understood by those skilled in the art that various modifications and changes can be made thereto without departing from the spirit and scope of the present invention defined by the appended claims and equivalents thereof.

1. A method of manufacturing a thin film, the method comprising:
providing a substrate;
providing a raw material;
vaporizing the raw material and loading the substrate into a chamber;
supplying the vaporized raw material to an interior of the chamber;
wherein a reaction gas is supplied to the chamber during or before the vaporized raw material is supplied; and
wherein the raw material is a precursor comprising at least one of the following chemical formulae: 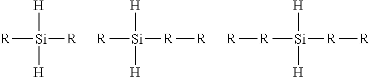
(where R is a functional group)

2. The method of manufacturing a thin film according to claim 1, wherein the reaction gas is reacted with the raw material to form a thin film and comprises at least one selected from an oxygen-containing gas, a nitrogen-containing gas, a hydrocarbon compound (CxHy, where 1≦x≦9, 4≦y≦20 and y>2x), a boron-containing gas and a silicon-containing gas.

3. The method of manufacturing a thin film according to claim 2, wherein the vaporized raw material is supplied together with a carrier gas comprising at least one selected from helium, argon and nitrogen.

4. The method of manufacturing a thin film according to claim 3, wherein the functional group of the raw material comprises at least one selected from a methyl group (—CH₃), an ethyl group (—C₂H₅), a benzyl group (—CH₂—C₆H₅), a phenyl group (—C₆H₅), an amine group (—NH₂), a nitro group (—NO), a hydroxyl group (—OH), a formyl group (—CHO) and a carboxyl group (—COOH).

5. The method of manufacturing a thin film according to claim 4, wherein a thin film formed on the substrate is an insulation film containing silicon.

6. The method of manufacturing a thin film according to claim 5, wherein the insulation film comprises at least one of an oxide film, a nitride film, a carbide film, an oxide-nitride film, a carbide-nitride film, a boride-nitride film, and a carbide-boride-nitride film.

7. The method of manufacturing a thin film according to claim 1, wherein plasma is generated in the chamber and a thin film-manufacturing temperature is controlled in a range of 80 to 250 degrees to form a silicon oxide film.

8. The method of manufacturing a thin film according to claim 7, wherein the silicon oxide film is formed using a C₄H₁₂Si raw material.

9. The method of manufacturing a thin film according to claim 1, wherein plasma is generated in the chamber and a thin film-manufacturing temperature is controlled in a range of 100 to 500 degrees to form a silicon nitride film.

10. The method of manufacturing a thin film according to claim 9, wherein the silicon nitride film is formed using a C₄H₁₂Si raw material.

11. A method of manufacturing a thin film, the method comprising:
providing a substrate;
providing a raw material comprising a compound which has a basic structure of SiH₂ and functional groups comprising at least one of carbon, oxygen and nitrogen linearly coupled to both sides of the basic structure;
vaporizing the raw material and loading the substrate into a chamber; and
supplying the vaporized raw material to an interior of the chamber,
wherein a reaction gas is supplied to the chamber during or before the vaporized raw material is supplied.

12. The method of manufacturing a thin film according to claim 11, wherein the reaction gas is reacted with the raw material to form a thin film and comprises at least one selected from an oxygen-containing gas, a nitrogen-containing gas, a hydrocarbon compound (CxHy, where 1≦x≦9, 4≦y≦20 and y>2x), a boron-containing gas and a silicon-containing gas.

13. The method of manufacturing a thin film according to claim 12, wherein the vaporized raw material is supplied together with a carrier gas comprises at least one selected from helium, argon and nitrogen.

14. The method of manufacturing a thin film according to claim 13, wherein the functional group of the raw material comprises at least one selected from a methyl group (—CH₃), an ethyl group (—C₂H₅), a benzyl group (—CH₂—C₆H₅), a phenyl group (—C₆H₅), an amine group (—NH₂), a nitro group (—NO), a hydroxyl group (—OH), a formyl group (—CHO) and a carboxyl group (—COOH).

15. The method of manufacturing a thin film according to claim 14, wherein a thin film formed on the substrate is an insulation film containing silicon.

16. The method of manufacturing a thin film according to claim 15, wherein the insulation film comprises at least one of an oxide film, a nitride film, a carbide film, an oxide-nitride film, a carbide-nitride film, a boride-nitride film, and a carbide-boride-nitride film.

17. The method of manufacturing a thin film according to claim 11, wherein plasma is generated in the chamber and a thin film-manufacturing temperature is controlled in a range of 80 to 250 degrees to form a silicon oxide film.

18. The method of manufacturing a thin film according to claim 17, wherein the silicon oxide film is formed using a C₄H₁₂Si raw material.

19. The method of manufacturing a thin film according to claim 11, wherein plasma is generated in the chamber and a thin film-manufacturing temperature is controlled in a range of 100 to 500 degrees to form a silicon nitride film.

20. The method of manufacturing a thin film according to claim 19, wherein the silicon nitride film is formed using a C₄H₁₂Si raw material.
